(19) United States
(12) Patent Application Publication
(10) Pub. No.: US 2011/0177456 A1
(43) Pub. Date: Jul. 21, 2011

(54) METHOD OF MAKING LITHOGRAPHIC PRINTING PLATES

(76) Inventors: Mathias Jarek, Bad Gandersheim (DE); Domenico Balbinot, Osterode am Harz (DE)

(21) Appl. No.: 12/691,273

(22) Filed: Jan. 21, 2010

(51) Int. Cl. G03F 7/20

(52) U.S. Cl. 430/302

(57) ABSTRACT

Lithographic printing plates can be provided by imagewise exposing a negative-working lithographic printing plate precursor comprising an aluminum-containing substrate having thereon an imageable layer, to provide exposed and non-exposed regions in the imageable layer. This imaged element is then processed to remove the non-exposed regions in the imageable layer and to gum the resulting image in a single step without an intermediate rinsing step by using an aqueous alkaline solution having a pH of at least 9. The aqueous alkaline solution includes an organic amine having a boiling point of less than 300° C., a film-forming hydrophilic polymer, and optionally an anionic or nonionic surfactant.

### FIELD OF THE INVENTION

This invention relates to a method of providing lithographic printing plates off-press using a simplified processing solution (developer) that contains a particular volatile organic amine. The invention uses a single processing solution that both develops and protects the imaged surface before the imaged element is used in lithographic printing.

### BACKGROUND OF THE INVENTION

Radiation-sensitive compositions are routinely used in the preparation of imageable materials including lithographic printing plate precursors. Such compositions generally include a radiation-sensitive component, an initiator system including an initiator and a radiation absorbing compound, and a polymeric binder, each of which has been the focus of research to provide various improvements in physical properties, imaging performance, and image characteristics.

Recent developments in the field of printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates, exposed regions in the radiation-sensitive compositions are hardened and unexposed regions are washed off during development. For positive-working printing plates, the exposed regions are dissolved in a developer and the unexposed regions become an image.

Various radiation-sensitive compositions that can be used to generate free radicals upon thermal imaging and imageable elements containing same are described in numerous publications. Such negative-working imageable elements are generally processed after imaging using aqueous high pH developers. Development using gums is described for example, in EP Publications 1,751,625 (Van Damme et al. published as WO 2005/111727) 1,788,429 (Loccufier et al. et al.), 1,788,430 (Williamson et al.), 1,788,431 (Van Damme et al.), 1,788,434 (Van Damme et al.), 1,788,441 (Van Damme), 1,788,442 (Van Damme), 1,788,443 (Van Damme), 1,788,444 (Van Damme), and 1,788,450 (Van Damme), and WO 2007/057442 (Cries et al.). The imageable elements used in these references have a protective oxygen-barrier overcoat, an intermediate layer between the substrate and imageable layer, or both.

Simple processing (development) of imaged elements has become a goal of workers in the lithographic art. For example, U.S. Patent Application Publication 2009/0098482 (Ray et al.) describes negative-working imageable elements that are sensitive to infrared radiation and can be simply processed (developed and “gummed”) using finishing gum solutions without the need for a conventional alkaline developer. This reduces the amount of processing equipment that is needed, costs, and consumption of processing solution.

In addition, U.S. Patent Application Publication 2009/0142702 (Ray et al.) describes the use of gums to develop imaged UV-sensitive, negative-working imageable elements that contain specific nonpolymeric diamide additives.

U.S. Patent Application Publication 2009/0186301 (Ray et al.) describes the use of a single non-silicate processing solution to both develop and protect images in imaged positive-working lithographic printing plate precursors.

U.S. Patent Application Publication 2009/1097206 (Ray et al.) describes the use of a “fresh” sample of processing solution to provide images in either positive-working or negative-working imageable elements.

U.S. Pat. No. 4,179,208 (Martino) describes a processing machine that uses an alkaline developer that is modified by the addition of a small amount of “gum”, and the developer is re-used or replenished but there are no details about the composition of this modified developer.

In addition, US Patent Application Publication 2009-0148794 describes a method of processing photosensitive printing plate precursors in a single step in which the processing solution comprises a surfactant, water-soluble film-forming hydrophilic polymer, and an alkaline agent to provide a pH of from 9.5 to 13.5.

Generally, an imagewise exposed negative-working lithographic printing plate precursor is developed (processed) and separately rinsed (washed) or “gummed” before the printing plates are used for printing. Other printing plates are prepared in a single processing and gumming step at relatively neutral pH (less than 8). However, such processing may not always effectively develop the image so that “cleanout” is incomplete. Improved cleanout may be possible with higher alkalinity, but leaving the high pH developer on the imaged printing plate may damage the aluminum substrate. Thus, the industry has typically rinsed or washed, and gummed, the developed printing plate after high pH processing.

### SUMMARY OF THE INVENTION

This invention provides a method of providing a lithographic printing plate comprising:

A) imagewise exposing a negative-working lithographic printing plate precursor comprising an aluminum-containing substrate having thereon an imageable layer, to provide exposed and non-exposed regions in the imageable layer, and

B) removing the non-exposed regions in the imageable layer and gumming the resulting image in a single step without an intermediate rinsing step by using an aqueous alkaline solution having a pH of at least 9,

wherein the imageable layer comprises a free radically polymerizable component, a free radical forming initiator, a radiation absorbing compound, and a polymeric binder that contains no pendant ethylenically unsaturated groups, and

wherein the aqueous alkaline solution comprises an organic amine having a boiling point of less than 300° C., a film-forming hydrophilic polymer, and optionally an anionic or nonionic surfactant.

The method of this invention provides a number of advantages that were not expected to us. For example, we have found a way to develop imaged negative-working lithographic printing plate precursors using relatively high alkaline processing solutions that also provide “gumming” to protect the imaged printing plate surface. Because the aqueous alkaline solution includes an organic amine and a film-forming hydrophilic polymer, we can achieve high cleanout of the non-exposed imaging layer formulation without damaging the underlying hydrophilic aluminum substrate.

### DETAILED DESCRIPTION OF THE INVENTION

Unless the context indicates otherwise, when used herein, the terms “imageable element”, “negative-working imageable element”, and “lithographic printing plate precursor” are meant to be references to elements useful in the practice of the present invention.

Unless the context indicates otherwise, when used herein, the term “aqueous alkaline solution” is meant to be a reference to a processing solution useful in the practice of this invention.

In addition, unless the context indicates otherwise, the various components described herein such as “free radically polymerizable component”, “radiation absorbing compound”, “polymeric binder”, “initiator”, “film-forming “hydrophilic polymer”, “organic amine”, “surfactant”, and similar terms also refer to mixtures of such components. Thus, the use of the articles “a”, “an”, and “the” are not necessarily meant to refer to only a single component.

Moreover, unless otherwise indicated, percentages refer to percents by dry weight.

The imageable elements used in this invention can be generally “single-layer” imageable elements by which we mean that the elements contain only one imageable layer that is essential for imaging and this layer is the outermost layer. Other imageable elements can also include a water-soluble or water-dispersible topcoat disposed over the imageable layer.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

“Graft” polymer or copolymer refers to a polymer having a side chain that has a molecular weight of from about 200.

The term “polymer” refers to high and low molecular weight polymers including oligomers and includes homopolymers and copolymers.

The term “copolymer” refers to polymers that are derived from two or more different monomers.

The term “backbone” refers to the chain of atoms in a polymer to which a plurality of pendant groups are attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Imageable Layers

The imageable elements include a radiation-sensitive composition disposed on a suitable substrate to form an imageable layer. The imageable elements may have any utility wherever there is a need for an applied coating that is crosslinkable using suitable imaging radiation, and particularly where it is desired to remove non-exposed regions of the coating instead of exposed regions. The radiation-sensitive compositions can be used to prepare an imageable layer in imageable elements such as printed circuit boards for integrated circuits, microoptical devices, color filters, photomasks, and printed forms such as lithographic printing plate precursors that are defined in more detail below.

The free radically polymerizable component used in the radiation-sensitive composition consists of one or more compounds that have one or more ethylenically unsaturated polymerizable or crosslinkable groups that can be polymerized or crosslinked using free radical initiation. For example, the free radically polymerizable component can be ethylenically unsaturated monomers, oligomers, and crosslinkable polymers, or various combinations of such compounds.

Thus, suitable ethylenically unsaturated compounds that can be polymerized or crosslinked include ethylenically unsaturated polymerizable monomers that have one or more of the polymerizable groups, including unsaturated esters of alcohols, such as (meth)acrylate esters of polyols. Oligomers and/or prepolymers, such as urethane (meth)acrylates, epoxide (meth)acrylates, polyester (meth)acrylates, polyether (meth)acrylates, free-radical crosslinkable polymers, and unsaturated polyester resins can also be used. In some embodiments, the radically polymerizable component may comprise carboxy groups.

Particularly useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers, or combinations of these classes of materials. More particularly useful free radically polymerizable compounds include those derived from urea urethane (meth)acrylates or urethane (meth)acrylates having multiple polymerizable groups. For example, a most preferred free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Other useful free radically polymerizable compounds include NK Ester A-DPH (dipentaerythritol hexaacrylate) that is available from Kowa American, and free radically polymerizable compounds are available from Sartomer Company, Inc. such as Sartomer 399 (dipentaerythritol pentaacrylate), Sartomer 355 (di-trimethylolpropane tetraacrylate), Sartomer 295 (pentaerythritol tetraacrylate), Sartomer 415 [ethoxylated (20) trimethylolpropane triacrylate], and others that would be readily apparent to one skilled in the art.

Also useful are urea urethane (meth)acrylates and urethane (meth)acrylates described in U.S. Pat. Nos. 6,582,882 (noted above), 6,899,994 (noted above), and 7,153,632 (Saraiya et al.) and WO 2007/077207, all of which are incorporated herein by reference.

Numerous other free radically polymerizable compounds are known to those skilled in the art and are described in considerable literature including Photoreactive Polymers The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (noted above), beginning with paragraph [0170].

The free radically polymerizable component is present in the radiation-sensitive composition in an amount sufficient to render the composition insoluble in the aqueous alkaline solution (developer) described below after exposure to suitable radiation. This is generally from about 10 to about 70 weight % and typically from about 20 to about 50 weight % based on the dry weight of the radiation-sensitive composition.

The radiation-sensitive composition includes an initiator composition containing a free radical forming initiator that is capable of generating radicals sufficient to initiate polymerization of the radically polymerizable component upon exposure to the appropriate imaging radiation. The initiator composition may be responsive, for example, to electromagnetic radiation in the infrared spectral regions, corresponding to the broad spectral range of from about 700 nm to about 1400 nm, and typically from about 700 nm to about 1200 nm. Alternatively, the initiator composition may be responsive to exposing radiation in the violet region of from about 250 to about 450 nm and typically from about 300 to about 450 nm.

There are numerous compounds known in the literature that can be used in this manner including but not limited to, organic boron salts, s-triazines, benzoyl-substituted compounds, onium salts (such as iodonium, sulfonium, diazonium, and phosphonium salts), trihaloalkyl-substituted compounds, metallocenes (such as titanocenes), ketoximes, thio compounds, organic peroxides, or a combination of two or more of these compounds. Hexaarylbiimidazoles, onium compounds, and thiol compounds as well as mixtures of two or more thereof are desired coinitiators or free radical generators, and especially hexaarylbiimidazoles and mixtures thereof with thiol compounds are useful.

Suitable hexaarylbiimidazoles are for example represented by the following formula:

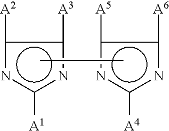

wherein A¹-A⁶ are substituted or unsubstituted C₅-C₂₀ aryl groups that are identical or different from each other and in whose rings one or more carbon atoms can optionally be substituted by heteroatoms selected from O, N and S. Suitable substituents for the aryl groups are those that do not inhibit the light-induced dissociation to triarylimidazolyl radicals, for example halogen atoms (fluorine, chlorine, bromine, and iodine), —CN, C₁-C₆ alkyl (optionally with one or more substituents selected from halogen atoms, —CN and —OH), C₁-C₆ alkoxy, C₁-C₆ alkylthio, and (C₁-C₆ alkyl) sulfonyl.

The aryl groups include but are not limited to, substituted and unsubstituted phenyl, biphenyl, naphthyl, pyridyl, furyl and thienyl groups. Useful aryl groups are substituted and unsubstituted phenyl groups such as halogen-substituted phenyl groups.

Suitable hexaarylbiimidazoles are also described in U.S. Pat. Nos. 4,565,769 (Dueber et al.) and 3,445,232 (Shirey) and can be prepared according to known methods, such as the oxidative dimerization of triarylimidazoles.

One or more coinitiators also can be used in amounts that are known in the art.

Other suitable initiator compositions comprise compounds that include but are not limited to, amines (such as alkanol amines), thiol compounds, N-phenyl glycine and derivatives thereof, N,N-dialkylaminobenzoic acid esters, N-arylglycines and derivatives thereof (such as N-phenylglycine), aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety, “co-initiators” described in U.S. Pat. No. 5,629,354 (West et al.), oxime ethers and oxime esters (such as those derived from benzoin), α-hydroxy or α-amino-acetophenones, alkyltriarylborates, trihalogenomethylarylsulfones, benzoin ethers and esters, peroxides (such as benzoyl peroxide), hydroperoxides (such as cumyl hydroperoxide), azo compounds (such as azo bis-isobutyronitrile) as described for example in U.S. Pat. No. 4,565,769 (Dueber et al.), borate and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). Other known initiator composition components are described for example in U.S Patent Application Publication 2003/0064318 (Huang et al.).

The IR-radiation sensitive initiator compositions used in this invention generally comprise an onium salt including but not limited to, a sulfonium, oxysulfoxonium, oxysulfonium, sulfoxonium, ammonium, selenonium, arsonium, phosphonium, diazonium, or halonium salt. Further details of useful onium salts, including representative examples, are provided in U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), 6,051,366 (Baumann et al.), and 7,368,215 (Munnelly et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art.

In one embodiment, the onium salt has a positively-charged iodonium, (4-methylphenyl)[4-(2-methylpropyl)phenyl]-moiety and a suitable negatively charged counterion. A representative example of such an iodonium salt is available as Irgacure° 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

Some useful boron components include organic boron salts that include an organic boron anion such as those described in U.S. Pat. No. 6,569,603 (noted above) that is paired with a suitable cation such as an alkali metal ion, an onium, or a cationic sensitizing dye. Useful onium cations include but are not limited to, ammonium, sulfonium, phosphonium, iodonium, and diazonium cations. Iodonium salts and particularly iodonium borates are useful as initiator compounds. They may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the IR radiation-sensitive composition.

Useful IR radiation-sensitive initiator compositions can comprise one or more diaryliodonium borate compounds, each of which is represented by the following Structure (II):

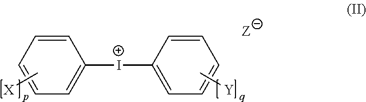

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono- and poly-, branched and linear haloalkyls), substituted or unsubstituted alkyloxy having 1 to 20 carbon atoms (for example, substituted or unsubstituted methoxy, ethoxy, iso-propoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). For example, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and in some embodiments, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated by this invention but the “symmetric” compounds are useful (that is, they have the same groups on both phenyl rings). In addition, two or more adjacent X or Y groups can be combined to form a fused carbocyclic or heterocyclic ring with the respective phenyl groups. The X and Y groups can be in any position on the phenyl rings but preferably they are at the 2- or 4-positions, and more preferably at the 4-position, on either or both phenyl rings.

Despite what type of X and Y groups are present in the iodonium cation, the sum of the carbon atoms in the X and Y substituents is from 6, or from 8 to 40. Thus, in some compounds, one or more X groups can comprise from about 6 carbon atoms, and Y does not exist (q is 0). Alternatively, one or more Y groups can comprise from 6 or more carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure II, p and q are independently 0 or integers of 1 to 5, provided that either p or q is at least 1. For example, both p and q can be 1. Thus, it is understood that the carbon atoms in the phenyl rings that are not substituted by X or Y groups have a hydrogen atom at those ring positions.

Z⁻ is an organic borate anion represented by the following Structure

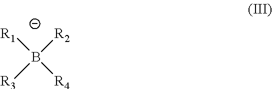

wherein R₁, R₂, R₃, and R₄ are independently substituted or unsubstituted alkyl groups having 1 to 12 carbon atoms (such as methyl, ethyl, n-propyl, iso-propyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms.

For example, R₁, R₂, R₃, and R₄ are independently substituted or unsubstituted alkyl or aryl groups as defined above, or at least 3 of R₁, R₂, R₃, and R₄ are the same or different substituted or unsubstituted aryl groups (such as substituted or unsubstituted phenyl groups). In some embodiments, all of R₁, R₂, R₃, and R₄ are the same or different substituted or unsubstituted aryl groups or, all of the groups are the same substituted or unsubstituted phenyl group. For example, Z⁻ is a tetraphenyl borate wherein the phenyl groups are substituted or unsubstituted.

Representative iodonium borate compounds useful in this invention include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]borate, 4-methoxyphenyl-4′-cyclohexylphenyliodonium tetrakis(penta-fluorophenyl)borate, 4-methylphenyl-4′-dodecylphenyliodonium tetrakis(4-fluorophenyl)borate, bis(dodecylphenyl)iodonium tetrakis(pentafluorophenyl)borate, and bis(4-t-butylphenyl)iodonium tetrakis(1-imidazolyl)borate. Useful compounds include bis(4-t-butylphenyl)iodonium tetraphenylborate, 4-methylphenyl-4′-hexylphenyliodonium tetraphenylborate, 2-methyl-4-t-butylphenyl-4′-methylphenyliodonium tetraphenylborate, and 4-methylphenyl-4′-cyclohexylphenyliodonium tetraphenylborate. Mixtures of two or more of these compounds can also be used in the initiator composition.

The initiator composition including one or more free radical forming initiators is generally present in the radiation-sensitive composition in an amount of from about 0.5% to about 30%, based on the total solids of the radiation-sensitive composition or the dry weight of the coated imageable layer. For example, the initiator composition is present in an amount of from about 2% to about 20 weight %. In the most embodiments, one or more diaryliodonium borate compounds generally comprise from about 10 to 100% of the initiator composition.

In some embodiments, the radiation-sensitive composition contains a UV sensitizer where the free-radical generating compound is UV radiation sensitive (that is at least 150 nm and up to and including 475 nm), thereby facilitating photopolymerization. In some other embodiments, the radiation sensitive compositions are sensitized to “violet” radiation in the range of at least 375 nm and up to and including 475 nm. Useful sensitizers for such compositions include certain pyrilium and thiopyrilium dyes and 3-ketocoumarins. Some other useful sensitizers for such spectral sensitivity are described for example, in 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated π-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Other useful sensitizers for the violet region of sensitization are the 2,4,5-triaryloxazole derivatives as described in WO 2004/074930 (Baumann et al.). These compounds can be used alone or with a co-initiator as described above. Useful 2,4,5-triaryloxazole derivatives can be represented by the Structure G-(Ar₁)₃ wherein Ar₁ is the same or different, substituted or unsubstituted carbocyclic aryl group having 6 to 12 carbon atoms in the ring, and G is a furan or oxazole ring, or the Structure G-(Ar₁)₂ wherein G is an oxadiazole ring. The Ar₁ groups can be substituted with one or more halo, substituted or unsubstituted alkyl, substituted or unsubstituted cycloalkyl, substituted or unsubstituted aryl, amino (primary, secondary, or tertiary), or substituted or unsubstituted alkoxy or aryloxy groups. Thus, the aryl groups can be substituted with one or more R′₁ through R′₃ groups, respectively, that are independently hydrogen or a substituted or unsubstituted alkyl group having from 1 to 20 carbon atoms (such as methyl, ethyl, iso-propyl, n-hexyl, benzyl, and methoxymethyl groups) substituted or unsubstituted carbocyclic aryl group having 6 to 10 carbon atoms in the ring (such as phenyl, naphthyl, 4-methoxyphenyl, and 3-methylphenyl groups), substituted or unsubstituted cycloalkyl group having 5 to 10 carbon atoms in the ring, a —N(R′₄)(R′₅) group, or a —OR′₆ group wherein R′₄ through R′₆ independently represent substituted or unsubstituted alkyl or aryl groups as defined above. At least one of R′₁ through R′₃ is an —N(R′₄)(R′₅) group wherein R′₄ and R′₅ are the same or different alkyl groups. Useful substituents for each Ar₁ group include the same or different primary, secondary, and tertiary amines.

Still another class of useful violet radiation sensitizers includes compounds represented by the Structure Ar₁-G-Ar₂ wherein Ar₁ and Ar₂ are the same or different substituted or unsubstituted aryl groups having 6 to 12 carbon atoms in the ring, or Ar₂ can be an arylene-G-Ar₁ or arylene-G-Ar₂ group, and G is a furan, oxazole, or oxadiazole ring. Ar₁ is the same as defined above, and Ar₂ can be the same or different aryl group as Ar₁. “Arylene” can be any of the aryl groups defined for Ar₁ but with a hydrogen atom removed to render them divalent in nature.

The IR radiation-sensitive composition sensitivity is provided by the presence of one or more infrared radiation absorbing compounds, chromophores, or sensitizers that absorb imaging radiation, or sensitize the composition to imaging infrared radiation having a λₘₐₓ of from about 700 nm and up to and including 1400 nm, and typically from about 700 to about 1200 nm.

Useful IR radiation absorbing compounds include various IR-sensitive dyes (“IR dyes”). Examples of suitable IR dyes comprising the desired chromophore include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. Nos. 5,208,135 (Patel et al.), 6,153,356 (Urano et al.), 6,264,920 (Achilefu et al.), 6,309,792 (Hauck et al.), 6,569,603 (noted above), 6,787,281 (Tao et al.), 7,135,271 (Kawaushi et al.), and EP 1,182,033A2 (noted above). Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.).

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (noted above), 6,264,920 (Achilefu et al.), 6,153,356 (noted above), 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Still other useful infrared radiation absorbing compounds are copolymers can comprise covalently attached ammonium, sulfonium, phosphonium, or iodonium cations and infrared radiation absorbing cyanine anions that have two or four sulfonate or sulfate groups, or infrared radiation absorbing oxonol anions, as described for example in U.S. Pat. No. 7,049,046 (Tao et al.).

The radiation absorbing compounds (or sensitizers) can be present in the radiation sensitive composition (or imageable layer) in an amount generally of at least 1% and up to and including 30% and typically at least 3 and up to and including 20%, based on total solids in the composition, that also corresponds to the total dry weight of the imageable layer. The particular amount needed for this purpose would be readily apparent to a skilled worker in the art.

The radiation-sensitive composition includes one or more polymeric binders that are generally used for off-press developability include any alkaline solution soluble (or dispersible) polymer having an acid value of from about 20 to about 400 (typically from about 30 to about 200). The following described polymeric binders are particularly useful in the manner but this is not an exhaustive list:

I. Polymers formed by polymerization of a combination or mixture of (a) (meth)acrylonitrile, (b) poly(alkylene oxide) esters of (meth)acrylic acid, and optionally (c) (meth)acrylic acid, (meth)acrylate esters, styrene and its derivatives, and (meth)acrylamide as described for example in U.S. Pat. No. 7,326,521 (Tao et al.) that is incorporated herein by reference. Some particularly useful polymeric binders in this class are derived from one or more (meth)acrylic acids, (meth)acrylate esters, styrene and its derivatives, vinyl carbazoles, and poly(alkylene oxide) (meth)acrylates.

II. Polymers having pendant allyl ester groups as described in U.S. Pat. No. 7,332,253 (Tao et al.) that is incorporated herein by reference. Such polymers may also include pendant cyano groups or have recurring units derived from a variety of other monomers as described in Col. 8, line 31 to Col. 10, line 3 of the noted patent.

III. Polymers having all carbon backbones wherein at least 40 and up to 100 mol % (and typically from about 40 to about 50 mol %) of the carbon atoms forming the all carbon backbones are tertiary carbon atoms, and the remaining carbon atoms in the all carbon backbone being non-tertiary carbon atoms. By “tertiary carbon”, we refer to a carbon atom in the all carbon backbone that has three valences filled with radicals or atoms other than a hydrogen atom (which fills the fourth valence). By “non-tertiary carbon”, we mean a carbon atom in the all carbon backbone that is a secondary carbon (having two valences filled with hydrogen atoms) or a quaternary carbon (having no hydrogen atoms attached). Typically, most of the non-tertiary carbon atoms are secondary carbon atoms. One way to represent a tertiary carbon atom in the all carbon backbone is with the following Structure (T-CARBON):

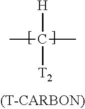

wherein T₂ is a group other than hydrogen provided that T₂ does not include an ethylenically unsaturated free radically reactive group (such as a —C═C— group). In many embodiments, T₂ is a pendant group selected from N-carbazole, aryl (defined similarly as for Ar below), halo, cyano, —C(═O)R, —C(═O)Ar, —C(═O)OR, —C(═O)OAr, —C(═O)NHR, and —C(═O)NHAr pendant groups, wherein R is hydrogen or an alkyl, cycloalkyl, halo, alkoxy, acyl, or acyloxy group, and Ar is an aryl group other than a styryl group. The quaternary carbon atoms present in the all carbon backbone of the polymeric binder can also have the same or different pendant groups filling two of the valences. For example, one or both valences can be filled with the same or different alkyl groups as defined above for R, or one valence can be filled with an alkyl group and another valence can be filled with a N-carbazole, aryl other than a styryl group, halo, cyano, —C(═O)R, —C(═O)Ar, —C(═O)OR, —C(═O)OAr, —C(═O)NHR, or —C(═O)NHAr pendant group, wherein R and Ar are as defined above. The pendant groups attached to the tertiary and quaternary carbons in the all carbon backbone can be the same or different and typically, they are different. It should also be understood that the pendant groups attached to the various tertiary carbon atoms can be the same throughout the polymeric molecule, or they can be different. For example, the tertiary carbon atoms can be derived from the same or different ethylenically unsaturated polymerizable monomers. Moreover, the quaternary carbon atoms throughout the polymeric molecule can have the same or different pendant groups.

In some embodiments of this invention, the polymeric binder can be represented by the following Structure:

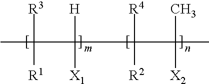

that is defined in more details in U.S. Patent Application Publication 2008-0280229 (Tao et al.) that is incorporated herein by reference.

Representative recurring units comprising tertiary carbon atoms can be derived from one or more ethylenically unsaturated polymerizable monomers selected from vinyl carbazole, styrene and derivatives thereof (other than divinylbenzene and similar monomers that provide pendant carbon-carbon polymerizable groups), acrylic acid, acrylonitrile, acrylamides, acrylates, and methyl vinyl ketone. As noted above, two or more different recurring units can be used. Similarly, representative recurring units with secondary or quaternary carbon atoms can be derived from one or more ethylenically unsaturated polymerizable monomers selected from methacrylic acid, methacrylates, methacrylamides, and α-methylstyrene.

IV. Polymeric binders that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups may be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. Nos. 4,874,686 (Urabe et al.), 7,729,255 (Tao et al.), 6,916,595 (Fujimaki et al.), and 7,041,416 (Wakata et al.) that are incorporated by reference, especially with respect to the general formulae (1) through (3) noted in EP 1,182,033A1.

V. Polymeric binders can have pendant 1H-tetrazole groups as described in U.S. Patent Application Publication 2009-0142695 (Baumann et al.) that is incorporated herein by reference.

VI. Still other useful polymeric binders may be homogenous, that is, dissolved in the coating solvent, or may exist as discrete particles and include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (noted above) and U.S. Pat. Nos. 6,309,792 (Hauck et al.), 6,352,812 (Shimazu et al.), 6,569,603 (noted above), and 6,893,797 (Munnelly et al.). Also useful are the vinyl carbazole polymers described in U.S. Pat. No. 7,175,949 (Tao et al.). Other useful polymeric binders are particulate poly(urethane-acrylic) hybrids that are distributed (usually uniformly) throughout the imageable layer. Each of these hybrids has a molecular weight of from about 50,000 to about 500,000 and the particles have an average particle size of from about 10 to about 10,000 nm (typically from about 30 to about 500 nm).

The polymeric binder is generally present in the radiation-sensitive composition (and imageable layer) in an amount of at least 2.5 and up to 70 weight %, and typically from about 10 to about 50 weight % based on the total solids in the composition and layer.

The radiation-sensitive composition (and imageable layer) can also include a variety of optional compounds including but not limited to, dispersing agents, humectants, biocides, plasticizers, surfactants for coatability or other properties, viscosity builders, contrast dyes or colorants other than those described above (such as crystal violet, methyl violet, ethyl violet, Victoria Blue B, Victoria Blue R, malachite green, and brilliant green), pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

### Imageable Elements

The imageable elements can be formed by suitable application of a radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition that is directly applied to the substrate without any intermediate layer.

The imageable element can also include a water-soluble or water-dispersible overcoat (also sometimes known as an “oxygen impermeable topcoat” or “oxygen barrier layer”) disposed over the imageable layer. Such overcoat layers can comprise one or more water-soluble poly(vinyl alcohol)s having a saponification degree of at least 90% and generally have a dry coating weight of at least 0.1 and up to and including 2 g/m² (typically from about 0.4 to about 2.5 g/m²) in which the water-soluble poly(vinyl alcohol)s comprise at least 60% and up to 99% of the dry weight of the overcoat layer.

The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.).

The substrate generally has a hydrophilic surface, or at least a surface that is more hydrophilic than the applied imageable layer on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

One useful substrate is composed of an aluminum support that may be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid-anodized aluminum support that provides a hydrophilic surface for lithographic printing.

Sulfuric acid anodization of the aluminum support generally provides an oxide weight (coverage) on the surface of from about 1.5 to about 5 g/m² and more typically from about 3 to about 4.3 g/m². Phosphoric acid anodization generally provides an oxide weight on the surface of from about 1.5 to about 5 g/m² and more typically from about 1 to about 3 g/m². When sulfuric acid is used for anodization, higher oxide weight (at least 3 g/m²) may provide longer press life.

The aluminum support may also be treated with, for example, a silicate, dextrine, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support may be treated with a phosphate solution that may further contain an inorganic fluoride (PF). The aluminum substrate can be electrochemically-grained, sulfuric acid-anodized, and treated with PVPA or PF using known procedures.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate may be coated with antistatic agents and/or slipping layers or a matte layer to improve handling and “feel” of the imageable element.

The substrate can also be a cylindrical surface having the imageable layer thereon, and thus be an integral part of the printing press. The use of such imaging cylinders is described for example in U.S. Pat. No. 5,713,287 (Gelbart).

A radiation-sensitive composition and optionally an overcoat composition containing the components described above can be applied as a solution or dispersion in a coating liquid using any suitable equipment and procedure, such as spin coating, knife coating, gravure coating, die coating, slot coating, bar coating, wire rod coating, roller coating, or extrusion hopper coating. The compositions can also be applied by spraying onto a suitable support (such as an on-press printing cylinder).

Illustrative of such manufacturing methods is mixing the free radically polymerizable component, initiator composition, polymeric binder, radiation absorbing compound, and any other components of the radiation-sensitive composition in a suitable coating solvent including water, organic solvents [such as glycol ethers including 1-methoxypropan-2-ol, methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], or mixtures thereof, applying the resulting solution to a substrate, and removing the solvent(s) by evaporation under suitable drying conditions. Some representative coating solvents (mixtures) and imageable layer formulations are described in the Invention Examples below. After proper drying, the coating weight of the imageable layer is generally at least 0.1 and up to and including 5 g/m² or at least 0.5 and up to and including 3.5 g/m².

### Imaging Conditions

During use, the imageable element is exposed to a suitable source of exposing radiation depending upon the radiation absorbing compound present in the radiation-sensitive composition, at a wavelength of from about 250 to about 450 nm or from about 700 to about 1500 nm. For example, imaging can be carried out using imaging or exposing radiation, such as from an infrared laser (or an array of lasers) at a wavelength of at least 700 nm and up to and including about 1400 nm and typically at least 700 nm and up to and including 1200 nm. Imaging can be carried out using imaging radiation at multiple wavelengths at the same time if desired.

The laser used to expose the imageable element is usually a diode laser (or array of diode lasers), because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Kodak Trendsetter platesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio). Imaging with infrared radiation can be carried out generally at imaging energies of at least 30 mJ/cm² and up to and including 500 mJ/cm², and typically at least 50 and up to and including 300 mJ/cm² depending upon the sensitivity of the imageable layer.

Useful UV and “violet” imaging apparatus include Prosetter (from Heidelberger Druckmaschinen, Germany), Luxel V-8 (from FUJI, Japan), Python (Highwater, UK), MakoNews, Mako 2, Mako 4 or Mako 8 (from ECRM, US), Micra (from Screen, Japan), Polaris and Advantage (from AGFA, Belgium), Laserjet (from Krause, Germany), and Andromeda® A750M (from Lithotech, Germany), imagesetters.

Imaging radiation in the UV to visible region of the spectrum, and particularly the UV region (for example at least 250 nm and up to and including 450 nm), can be carried out generally using energies of at least 0.01 mJ/cm² and up to and including 0.5 mJ/cm², and typically at least 0.02 and up to and including about 0.1 mJ/cm². It would be desirable, for example, to image the UV/visible radiation-sensitive imageable elements at a power density in the range of at least 0.5 and up to and including 50 kW/cm² and typically of at least 5 and up to and including 30 kW/cm², depending upon the source of energy (violet laser or excimer sources).

After imaging of negative-working imageable elements, a heating step might be used to accelerate the formation of a latent image. This heating step can be realized in so called “preheat units” that can be a separate machine or integrated into the processor that develops the imaged element. There are different types of preheat units. The most common ones use infrared radiation or hot air circulation, or combination thereof, to heat the imaged element. The temperature used for the purpose is from about 70 to about 200° C. and typically from about 90 to about 160° C. However, it can be advantageous to omit the preheating step to simplify the process for making printing plates.

A pre-rinse step might be carried out in a stand-alone apparatus or by manually rinsing the imaged element with water or the pre-rinse step can be carried out in a washing unit that is integrated in a processor used for developing the imaged element.

### Development and Printing

After thermal imaging, the imaged elements are generally processed “off-press” using aqueous alkaline processing solution having a pH of at least 9 and up to and including 13.5, or typically at least 9.5 and up to and including 12, or even from 10 to 12. Processing is carried out for a time sufficient to remove predominantly only the non-exposed regions of the imaged imageable layer to reveal the hydrophilic surface of the substrate, but not long enough to remove significant amounts of the exposed regions. The revealed hydrophilic surface repels inks while the exposed regions containing polymerized or crosslinked polymer accept ink. Thus, the non-exposed regions to be removed are “soluble” or “removable” in the aqueous alkaline solution because they are removed, dissolved, or dispersed within it more readily than the regions that are to remain. The term “soluble” also means “dispersible”.

Development can be accomplished using what is known as “manual” development, “dip” development, or processing with an automatic development apparatus (processor). In the case of “manual” development, development is conducted by rubbing the entire imaged element with a sponge or cotton pad sufficiently impregnated with a processing solution (described below), and optionally followed by rinsing with water. “Dip” development involves dipping the imaged element in a tank or tray containing the appropriate aqueous alkaline solution for about 10 to about 60 seconds (especially from about 20 to about 40 seconds) under agitation, optionally followed by rinsing with water with or without rubbing with a sponge or cotton pad. The use of automatic development apparatus is well known and generally includes pumping an aqueous alkaline solution into a developing tank or ejecting it from spray nozzles. The imaged element is contacted with the aqueous alkaline solution in an appropriate manner. The apparatus may also include a suitable rubbing mechanism (for example a brush or roller) and a suitable number of conveyance rollers. Some developing apparatus include laser exposure means and the apparatus is divided into an imaging section and a developing section.

The aqueous alkaline solution is used to both develop the imaged element by removing predominantly the non-exposed regions and also to provide a protective layer or coating over the entire imaged and developed surface. In this aspect, the aqueous alkaline solution behaves somewhat like a gum that is capable of protecting (or “gumming”) the lithographic image on the printing plate against contamination or damage (for example, from oxidation, fingerprints, dust, or scratches). The aqueous alkaline solution generally includes an organic amine having a boiling point of less than 300° C. (and typically of at least 50°), a film-forming hydrophilic polymer, and optionally an anionic or nonionic surfactant.

The pH of the aqueous alkaline solution can be adjusted by adding a suitable amount of a alkaline component such as alkali silicates (including metasilicates), alkali metal hydroxides (such as sodium hydroxide and potassium hydroxide), and quaternary ammonium hydroxides. Tap water can be used to make up the solution and generally provides from 45 to 98 weight % of the solution.

Useful organic amines are relatively volatile organic primary, secondary, and tertiary amines that include but are not limited to, alkanolamines (including cyclicalkyl amines), carbocyclic aromatic amines, and heterocyclic amines, that are present in a total amount of at least 0.1 weight % and generally up to and including 50 weight %, or from 0.1 to 25 weight %. Useful amines are mono-, di- and trialkanol amines such as monoethanolamine, diethanolamine, triethanolamine, and mono-n-propanolamine. Combinations of these compounds can be used if desired.

One or more film-forming water-soluble or hydrophilic polymers are present in the aqueous alkaline solution in an amount of at least 0.25 weight % and up to 30 weight % and typically from 1 to about 15 weight %.

Examples of useful polymers of this type include but are not limited to, gum arabic, pullulan, cellulose derivatives (such as hydroxymethyl celluloses, carboxymethylcelluloses, carboxyethylcelluloses, and methyl celluloses), starch derivatives [such as (cyclo)dextrins, starch esters, dextrins, carboxymethyl starch, and acetylated starch] poly(vinyl alcohol), poly(vinyl pyrrolidone), polyhydroxy compounds [such as polysaccharides, sugar alcohols such as sorbitol, miso-inosit, homo- and copolymers of (meth)acrylic acid or (meth)acrylamide], copolymers of vinyl methyl ether and maleic anhydride, copolymers of vinyl acetate and maleic anhydride, copolymers of styrene and maleic anhydride, and copolymers having recurring units with carboxy, sulfo, or phospho groups, or salts thereof. Useful hydrophilic polymers include gum arabic, (cyclo)dextrin, a polysaccharide, a sugar alcohol, or a homo- or copolymer having recurring units derived from (meth)acrylic acid. These polymers can be obtained from a variety of commercial sources or prepared using known procedures and starting materials.

The aqueous alkaline solution optionally includes one or more anionic, amphoteric, or nonionic surfactants (or both) in an amount of at least 0.25 and up to and including 50 weight %, and typically from 0.25 to 30 weight %. The surfactant is not specifically limited as long as it is compatible with the other components of the aqueous alkaline solution having a pH of at least 9.

Examples of useful anionic surfactants include but are not limited to, those with carboxylic acid, sulfonic acid, or phosphonic acid groups (or salts thereof). Anionic surfactants having sulfonic acid (or salts thereof) groups are particularly useful. For example, such anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypolyoxy-ethylenepropylsulfonates, salts of polyoxyethylene alkylsulfonophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphatic alkylester, salts of alkylsulfuric esters, sulfuric esters of polyoxy-ethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhydride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful as the primary anionic surfactant. Such surfactants can be obtained from various suppliers as described in McCutcheon's Emulsifiers & Detergents, 2007 Edition. Particularly useful anionic surfactants include alkylnaphthalenesulfonates, disulfonated alkydiphenyloxides, and alkylsulfonates.

Useful nonionic surfactants include, but are not limited to, polyoxyethylene alkyl ethers, polyoxyethylene phenyl ethers, polyoxyethylene 2-naphthyl ethers, polyoxyethylene alkyl phenyl ethers, polyoxyethylene polystyryl phenyl ethers, polyoxyethylene polyoxypropylene alkyl ethers, polyoxyethylene polyoxypropylene block polymers, partial esters of glycerin-aliphatic acids, partial esters of sorbitanaliphatic acid, partial esters of pentaertythritolaliphatic acid, propyleneglycolmonoaliphatic esters, partial esters of sucrosealiphatic acids, partial esters of polyoxyethylenesorbitanaliphatic acid, partial esters of polyoxyethylenesorbitolaliphatic acids, polyethyeleneglycolaliphatic esters, partial esters of poly-glycerinaliphatic acids, polyoxyethylenated castor oils, partial esters of polyoxyethyleneglycerinaliphatic acids, aliphatic diethanolamides, N,N-bis-2-hydroxyalkylamines, polyoxyethylene alkylamines, triethanolaminealiphatic ester, and trialkylamine oxides.

Useful amphoteric surfactants include but are not limited to, N-alkylamino acid triethanol ammonium salts, cocamidopropyl betaines, cocamidoalkyl glycinates, sodium salts of short chain alkylaminocarboxylates, N-2-hydroxyethyl-N-2-carboxyethyl fatty acid amidoethylamine sodium salts, and carboxylic acid amidoetherpropionates.

Additional optional components of the aqueous alkaline solutions used in this invention include antifoaming agents, buffers, biocides, complexing agents, and small amounts of water-miscible organic solvents such as reaction products of phenol with ethylene oxide and propylene oxide, benzyl alcohol, esters of ethylene glycol and propylene glycol with acids having 6 or less carbon atoms, sludge inhibitors (such as filter dyes and free-radical inhibitors), odorants, anti-corrosion agents, and dyes.

The aqueous alkaline solution (or developer) can be applied to the imaged element by rubbing, spraying, jetting, dipping, immersing, slot die coating (for example see FIGS. 1 and 2 of U.S. Pat. No. 6,478,483 of Maruyama et al.) or reverse roll coating (as described in FIG. 4 of U.S. Pat. No. 5,887,214 of Kurui et al.), or by wiping the outer layer with the solution or contacting it with a roller, impregnated pad, or applicator containing the gum. For example, the imaged element can be brushed with the solution, or it can be poured onto or applied by spraying the imaged surface with sufficient force to remove the non-exposed regions using a spray nozzle system as described for example in [0124] of EP 1,788,431A2 (noted above) and U.S. Pat. No. 6,992,688 (Shimazu et al.). Still again, the imaged element can be immersed in the solution and rubbed by hand or with an apparatus.

The aqueous alkaline solution can also be applied in a processing unit (or station) in a suitable apparatus that has at least one roller for rubbing or brushing the imaged element while the solution is applied. By using such a processing unit, the non-exposed regions of the imaged layer may be removed from the substrate more completely and quickly. Residual solution may be removed (for example, using a squeegee or nip rollers) or left on the resulting printing plate without any rinsing step. Excess solution can be collected in a tank and used several times, and replenished if necessary from a reservoir. The aqueous alkaline solution replenisher can be of the same concentration as that used in processing, or be provided in concentrated form and diluted with water at an appropriate time.

Following processing, the resulting lithographic printing plate can be used for printing with or without a separate rinsing step using water.

The resulting lithographic printing plate can also be baked in a postbake operation can be carried out, with or without a blanket or floodwise exposure to UV or visible radiation using known conditions. Alternatively, a blanket UV or visible radiation exposure can be carried out, without a postbake operation.

Printing can be carried out by applying a lithographic printing ink and fountain solution to the printing surface of the imaged and developed element. The fountain solution is taken up by the non-imaged regions, that is, the surface of the hydrophilic substrate revealed by the imaging and processing steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The present invention provides at least the following embodiments and combinations thereof.

### Embodiment 1

A method of providing a lithographic printing plate comprising:

A) imagewise exposing a negative-working lithographic printing plate precursor comprising an aluminum-containing substrate having thereon an imageable layer, to provide exposed and non-exposed regions in the imageable layer, and

B) removing the non-exposed regions in the imageable layer and gumming the resulting image in a single step without an intermediate rinsing step by using an aqueous alkaline solution having a pH of at least 9,

wherein the imageable layer comprises a free radically polymerizable component, a free radical forming initiator, a radiation absorbing compound, and a polymeric binder that contains no pendant ethylenically unsaturated groups, and

wherein the aqueous alkaline solution comprises an organic amine having a boiling point of less than 300° C., a film-forming hydrophilic polymer, and optionally an anionic or nonionic surfactant.

### Embodiment 2

The method of embodiment 1 wherein the amine is an alkanolamine that is present in an amount of at least 0.1 weight %.

### Embodiment 3

The method of embodiment 1 or 2 wherein the amine is monoethanolamine, diethanolamine, triethanolamine, or a combination thereof, that is present in an amount of from 0.1 to 25 weight %.

### Embodiment 4

The method of any of embodiments 1 to 3 wherein the negative-working lithographic printing plate is sensitive to radiation having a wavelength of from 700 to 1400 nm, and the radiation absorbing compound is an infrared radiation absorbing dye.

### Embodiment 5

The method of any of embodiments 1 to 4 wherein the polymeric binder comprises pendant acid groups and has an acid number of from about 20 to about 400 mg KOH/g of polymeric binder.

### Embodiment 6

The method of any of embodiments 1 to 5 wherein the film-forming hydrophilic polymer is gum Arabic, a (cyclo)dextrin, a polysaccharide, sugar alcohol, or a polymer having recurring units derived from (meth)acrylic acid, and this hydrophilic polymer is present in an amount of at least 0.25 weight %.

### Embodiment 7

The method of any of embodiments 1 to 6 wherein the aqueous solution comprises one or more nonionic or anionic surfactants in an amount of from 0.25 to 50 weight %.

### Embodiment 8

The method of any of embodiments 1 wherein the free radical forming initiator is a diaryliodonium borate.

### Embodiment 9

The method of any of embodiments 1 to 8 wherein the lithographic printing plate precursor further comprising a water-soluble topcoat directly disposed on the imageable layer.

### Embodiment 10

The method of any of embodiments 1 to 9 wherein the aqueous alkaline solution has a pH of from 9.5 to 12.

### Embodiment 11

The method of any of embodiments 1 to 10 wherein the polymeric binder is present in the imageable layer in an amount of from 2.5 to 75 weight %.

### Embodiment 12

The method of any of embodiments 1 to 11 wherein the aluminum-containing substrate that has been treated with a poly(vinyl phosphonic acid) before the imageable layer was applied.

The following Examples are provided to illustrate the present invention and are not meant to be limiting in any manner.

### Invention Example 1

An aqueous alkaline solution of the present invention was prepared using the following components to have a final pH of about 10.2:

Diethanolamine (DEA) (3%),

Naxan® ABL alkyl naphthalene sulfonate, sodium salt (Nease Performance Chemicals, 5%),

Ethylan® HB4 aromatic ethoxylate (Akzo Nobel, 3%),

Sorbidex™ sorbitol (Cargill, 5%), and

Water (84%).

### Comparative Example 1

A conventional developer outside of the present invention was prepared with the following components and the pH was adjusted to 10.2 with sodium hydroxide:

Naxan® ABL alkyl naphthalene sulfonate, sodium salt (5%),

Ethylan® HB4 aromatic ethoxylate (3%),

Sorbidex™ sorbitol (5%), and

Water (84%).

### Comparative Example 2

Another conventional developer outside of the present invention was prepared using the following components to have a final pH of 7.2 without addition of sodium hydroxide:

Naxan® ABL alkyl naphthalene sulfonate, sodium salt (5%),

Ethylan® HB4 aromatic ethoxylate (3%),

Sorbidex™ sorbitol (5%), and

Water (87%).

Samples of commercially available thermal photopolymer plate precursors (Kodak® THERMALNEWS GOLD Digital Plate) were imagewise exposed and developed (processed) using each of the developers described above.

The results are provided below in the following TABLE I:

TABLE I

| | Invention | Comparative | Comparative |
|---|---|---|---|
| | Example 1 | Example 1 | Example 2 |
| Developability | good | good | partially retained |
| | | | coating |
| Toning of fresh | clear | clear | Toning |
| plates | | | |
| Toning after | clear | toning | Toning |
| humidity aging* | | | |

*Humidity aging was carried out for 24 hours at 40° C. and 80% relative humidity

It can be seen from the data in TABLE I that the developer with no alkalinity change (Comparative Example 2) did not adequately develop the imaged printing plate precursors.

The Comparative Example 1 developer could be used to develop the imaged printing plate precursors without any coating retention but toning was observed after humidity aging (humid aging at 40° C./80% relative humidity simulates storage of the developed printing plate over a weekend in a warm climate before being used for printing). Toning after humidity aging is caused by an attack of the alkaline developer on the aluminum substrate of the developed printing plates over the aging period.

The developer of Invention Example 1 was used successfully to develop the imaged printing plate precursors without causing any toning after humidity aging. There was no attack of the aluminum substrate observed after the humidity aging period because the remaining DEA evaporated after development.

A check of the surface pH of the aluminum substrate for Invention Example 1 was generally neutral while the surface pH of the aluminum substrate after use the Comparative Developer 1 developer was generally at the high alkalinity of pH 10.

The invention has been described in detail with particular reference to certain preferred embodiments thereof, but it will be understood that variations and modifications can be effected within the spirit and scope of the invention.

1. A method of providing a lithographic printing plate comprising:
A) imagewise exposing a negative-working lithographic printing plate precursor comprising an aluminum-containing substrate having thereon an imageable layer, to provide exposed and non-exposed regions in the imageable layer, and
B) removing the non-exposed regions in the imageable layer and gumming the resulting image in a single step without an intermediate rinsing step by using an aqueous alkaline solution having a pH of at least 9,
wherein the imageable layer comprises a free radically polymerizable component, a free radical forming initiator, a radiation absorbing compound, and a polymeric binder that contains no pendant ethylenically unsaturated groups, and
wherein the aqueous alkaline solution comprises an organic amine having a boiling point of less than 300° C., a film-forming hydrophilic polymer, and optionally an anionic or nonionic surfactant.

2. The method of claim 1 wherein the amine is an alkanolamine that is present in an amount of at least 0.1 weight %.

3. The method of claim 1 wherein the amine is monoethanolamine, diethanolamine, triethanolamine, or a combination thereof, that is present in an amount of from 0.1 to 25 weight %.

4. The method of claim 1 wherein the negative-working lithographic printing plate is sensitive to radiation having a wavelength of from 700 to 1400 nm, and the radiation absorbing compound is an infrared radiation absorbing dye.

5. The method of claim 1 wherein the polymeric binder comprises pendant acid groups and has an acid number of from about 20 to about 400 mg KOH/g of polymeric binder.

6. The method of claim 1 wherein the film-forming hydrophilic polymer is gum Arabic, a (cyclo)dextrin, a polysaccharide, a sugar alcohol, or a polymer having recurring units derived from (meth)acrylic acid, and this hydrophilic polymer is present in an amount of at least 0.25 weight %.

7. The method of claim 1 wherein the aqueous solution comprises one or more nonionic or anionic surfactants in an amount of from 0.25 to 50 weight %.

8. The method of claim 1 wherein the free radical forming initiator is a diaryliodonium borate.

9. The method of claim 1 wherein the lithographic printing plate precursor further comprising a water-soluble topcoat directly disposed on the imageable layer.

10. The method of claim 1 wherein the aqueous alkaline solution has a pH of from 9.5 to 12.

11. The method of claim 1 wherein the polymeric binder is present in the imageable layer in an amount of from 2.5 to 75 weight %.

12. The method of claim 1 wherein the aluminum-containing substrate that has been treated with a poly(vinyl phosphonic acid) before the imageable layer was applied.
